(19) United States
(12) Patent Application Publication
(10) Pub. No.: US 2025/0157784 A1
(43) Pub. Date: May 15, 2025

(54) ION ANGLE SENSOR

(71) Applicant: Applied Materials, Inc., Santa Clara, CA (US)

(72) Inventor: Chuang-Chia Lin, San Ramon, CA (US)

(21) Appl. No.: 18/388,490

(22) Filed: Nov. 9, 2023

(51) Int. Cl. H01J 37/147

(52) U.S. Cl. CPC H01J 37/1478; H01J 2237/24528; H01J 2237/24542; H01J 2237/24578

(57) ABSTRACT

Embodiments disclosed herein include an apparatus for measuring ion angles. In an embodiment, the apparatus comprises a first plate with an array of first openings, where the first plate is electrically conductive, and a second plate with an array of second openings below the first plate, where the second plate is electrically conductive. In an embodiment, an actuator is coupled to the first plate or the second plate, where the actuator is configured to displace one of the first plate or the second plate. In an embodiment, a third plate is below the second plate, where the third plate is electrically conductive.

### BACKGROUND

### 1) Field

Embodiments relate to the field of semiconductor manufacturing and, in particular, to ion angle sensors.

### 2) Description of Related Art

Plasma based processes are often used in one or more operations in order to manufacture semiconductor devices. Plasma based processes may include, but are not limited to, etching processes, surface treatment process, and the like. Extremely accurate control of the plasma is necessary in order to fabricate features on the wafer that have the small scale (e.g., nanometer scale) of advanced semiconductor devices. Plasma properties that are controlled may include the concentration of various elemental species within a plasma, ion energy distributions, electron energy distributions, and the like.

Optical analysis can be used to determine the identities and concentrations of various species in the plasma. For example, optical emission spectroscopy (OES) is an analytical technique that is often used. OES allows for measurement of the plasma during operation through an optical view port in the plasma chamber. However, plasma properties like ion energy distributions are more difficult to determine.

### SUMMARY

Embodiments disclosed herein include an apparatus for measuring ion angles. In an embodiment, the apparatus comprises a first plate with an array of first openings, where the first plate is electrically conductive, and a second plate with an array of second openings below the first plate, where the second plate is electrically conductive. In an embodiment, an actuator is coupled to the first plate or the second plate, where the actuator is configured to displace one of the first plate or the second plate. In an embodiment, a third plate is below the second plate, where the third plate is electrically conductive.

Embodiments further comprise an apparatus that comprises a substrate and a sensor on the substrate. In an embodiment, the sensor comprises a collector plate and a first plate with first openings over the collector. In an embodiment, the first plate is configured to be displaced in a plane substantially parallel to a top surface of the collector plate. In an embodiment, a second plate with second openings is over the first plate. As used herein, “substantially parallel” may refer to two planes that are within 10° of being perfectly parallel with each other. That is, system tolerances (e.g., manufacturing tolerances, assembly tolerances, and/or mechanical performance) may not allow for the first plate, the second plate, and the collector plate to be positioned and displaceable with respect to each other in perfectly parallel planes.

Embodiments further comprise an apparatus that comprises a substrate with a plurality of sensors distributed across a surface of the substrate. In an embodiment, each sensor comprises a collector, where the collector is configured to measure a current induced by ions that collide with the collector. The sensor further comprises an ion filter over the collector, where the ion filter comprises a first plate with first openings and a second plate with second openings over the first plate. In an embodiment, one or both of the first plate and the second plate are displaceable in a plane substantially parallel to a top surface of the collector plate.

### BRIEF DESCRIPTION OF THE DRAWINGS

FIG. 1A is a cross-sectional illustration of a retarded field energy analyzer (RFEA) with a displaceable plate in a first orientation, in accordance with an embodiment.

FIG. 1B is a cross-sectional illustration of the RFEA in a second orientation, in accordance with an embodiment.

FIG. 2 is a cross-sectional illustration of an RFEA with at least one displaceable plate and an electron filter, in accordance with an embodiment.

FIG. 3 is a cross-sectional illustration of an RFEA with at least one displaceable plate, an electron filter, and a reflected ion and electron filter, in accordance with an embodiment.

FIG. 4A is a cross-sectional illustration of an RFEA with a first displaceable plate and a second displaceable plate in a first orientation, in accordance with an embodiment.

FIG. 4B is a cross-sectional illustration of the RFEA in a second orientation, in accordance with an embodiment.

FIG. 5A is a plan view illustration of a first plate of an RFEA, in accordance with an embodiment.

FIG. 5B is a plan view illustration of a second plate of the RFEA, in accordance with an embodiment.

FIG. 5C is a plan view illustration of a second plate of the RFEA with slotted holes, in accordance with an embodiment.

FIG. 6 is a plan view illustration of a sensor system with a substrate and a plurality of RFEAs, in accordance with an embodiment.

FIG. 7 is a cross-sectional illustration of a sensor system with an RFEA over a substrate, in accordance with an embodiment.

FIG. 8 is a plan view illustration of a sensor system with an RFEA that is driven by an underlying actuator, in accordance with an embodiment.

FIG. 9A is a plan view illustration of a plate with a first configuration, in accordance with an embodiment.

FIG. 9B is a plan view illustration of a plate with a second configuration, in accordance with an embodiment.

FIG. 10 is a process flow diagram depicting a process for using an RFEA to measure ion angles, in accordance with an embodiment.

FIG. 11 is a process flow diagram depicting a process for using an RFEA to measure ion angles and ion energy distributions, in accordance with an embodiment.

FIG. 12 illustrates a block diagram of an exemplary computer system that may be used in conjunction with a processing tool, in accordance with an embodiment.

### DETAILED DESCRIPTION

Systems described herein include retarded field energy analyzers (RFEAs) with one or more displaceable plates to measure ion energy from a plasma at various angles. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, plasma monitoring has several limitations when using existing analytical techniques. One solution is to use a retarded field energy analyzer (RFEA). An RFEA includes a series of electrically conductive plates that are held at different voltages. The plates can be configured so that electrons are repelled and ions are attracted to a collector plate. Current passing in the collector plate can then be correlated to the ion energy distribution. In their existing form, RFEA solutions are agnostic to the angle that the ion intersects the substrate or wafer. Instead, ions at all angles are treated as the same. However, measurements of different ion angles is critical for maintaining high yielding processes in advanced processing environments. Accordingly, embodiments disclosed herein include an ion filtering system that allows for selectively measuring different ion angles of a plasma source. In some embodiments, the improved RFEA includes at least a first ion filter plate and a second ion filter plate above a collector. One or both of the first ion filter plate and the second ion filter plate may be displaceable with respect to each other. As such, openings through the first ion filter plate and the second ion filter plate can be modulated to provide paths from the plasma to the collector that intersect the collector at different angles. Therefore, embodiments disclosed herein allow for the collection and recordation of the ions at specific angles. This information can be used to more finely tune plasma processing operations in order to provide more accurate and controllable outcomes on the wafer surface.

In an embodiment, the ion filter plates may be displaced through the use of one or more actuators. The actuators may include a micro-electromechanical system (MEMS) actuator or any other small form factor actuating device. The actuators may include electrostatic actuators, piezoelectric actuators, thermally driven actuators, or memory-alloy actuators. For example, an electrostatic comb drive may be used in some embodiments.

In an embodiment, the RFEA may also include additional plates in order to improve measurement accuracy. For example, an electron filter may be provided above the ion filters. The electron filter may be used to repel electrons from the plasma so that they do not reach the collector. A reflection filter may also be provided between the ion filters and the collector. The reflection filter may attract electrons that are ejected from the collector when ions collide with the collector.

In an embodiment, the RFEA may be provided on a substrate that is inserted into a plasma chamber. The substrate may be a wafer form factor substrate (e.g., 300 mm, 450 mm, etc.). In some embodiments, a plurality of RFEAs may be distributed across the substrate in order to provide a spatial mapping of the ion energy distribution as well as the ion angle distribution.

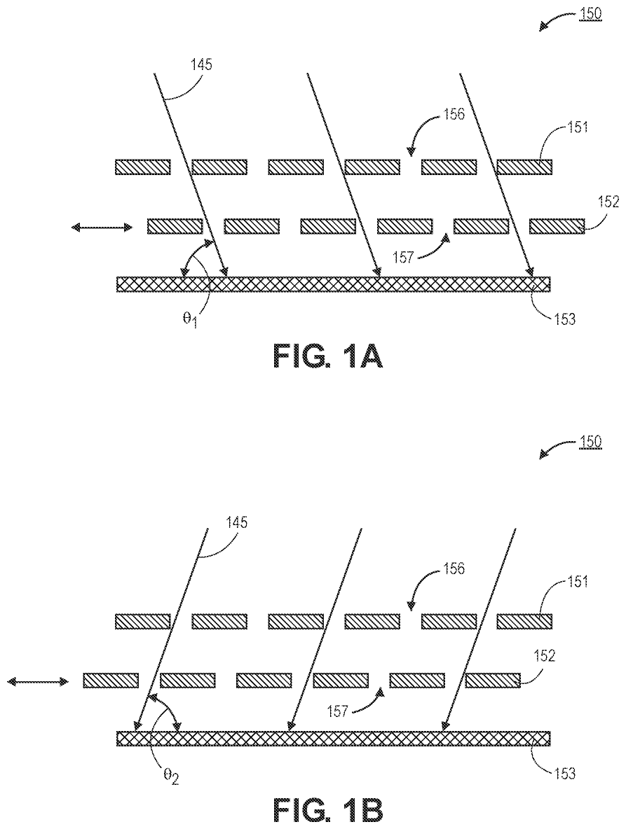

Referring now to FIG. 1A, a cross-sectional illustration of an RFEA sensor 150 is shown, in accordance with an embodiment. In an embodiment, the sensor 150 may include a plurality of plates 151, 152, and 153 that are arranged in a vertical stack over each other. While shown as floating over each other, it is to be appreciated that an insulating spacer (not shown) may be provided between each of the plates 151, 152, and 153. The plates 151, 152, and 153 may have similar dimensions (e.g., length, width, thickness) to each other. Though, the plates 151, 152, and 153 need not be uniform in some embodiments.

In an embodiment, the plates 151, 152, and 153 are electrically conductive materials. The plates 151, 152, and 153 may be a metallic material, an alloy, or the like, that is compatible with the plasma environment being investigated. For example, the plates 151, 152, and 153 may comprise nickel, an alloy including nickel, stainless steel, aluminum, titanium, or the like. In some embodiments, all of the plates 151, 152, and 153 are the same material. Though, in other embodiments, plates 151, 152, and 153 may include different materials. For example, plates 151 and 152 may comprise a first material, and the plate 153 may comprise a second material that is different than the first material.

In an embodiment, the first plate 151 and the second plate 152 may be ion filter plates. The ion filter plates 151 and 152 are designed to allow ions from the plasma to selectively pass through openings 156 and 157 in the plates 151 and 152. The openings 156 and the openings 157 may be substantially the same size (e.g., diameter, width, etc.), or the openings 156 may be different in size than the openings 157. As used herein, “substantially the same size” may refer to dimensions being within ten percent of each other. In an embodiment, the first plate 151 and the second plate 152 may be held at different voltages in order to discriminate between ions with different energies. As the voltage difference between the first plate 151 and the second plate 152 is swept through a desired range, ions with different energies are allowed to pass through the openings 156 and 157. After the ions pass through the first plate 151 and the second plate 152, the ions collide with the third plate 153, which may be referred to as a collector. The ions colliding with the third plate 153 generate current in the third plate 153. The third plate 153 may be coupled to a charge collection circuit (not shown) that is capable of quantifying the current generated in the third plate 153. As such, an ion energy distribution can be calculated.

When the first plate 151 and the second plate 152 are aligned with each other so that openings 156 overlap openings 157, the angle of the ions interacting with the third plate 153 may be approximately 90°. However, as noted above, the ability to discretely measure the ion energy distribution for different attack angles is beneficial for some process monitoring situations. Accordingly, at least one of the first plate 151 and the second plate 152 may be coupled to an actuator in order to displace the first plate 151 relative to the second plate 152. In FIG. 1A, the second plate 152 is coupled to an actuator as indicated by the double sided arrow adjacent to the second plate. In some embodiments, the actuator may displace the second plate 152 in a plane that is substantially parallel to a top surface of the third plate 153. For example, displacement of the second plate 152 may not significantly change the vertical distance between the first plate 151 and the second plate 152 or the vertical distance between the second plate 152 and the third plate 153. In an embodiment, the actuator may be a MEMS actuator or any other small form factor actuating device. The actuator may include an electrostatic actuator, a piezoelectric actuator, a thermally driven actuator, or a memory-alloy actuator. For example, an electrostatic comb drive may be used in some embodiments.

As shown in FIG. 1A, the second plate 152 is laterally displaced so that the openings 157 are offset from the openings 156 in the first plate 151. Offsetting the openings 156 and 157 blocks the vertical path of ions from an overlying plasma (not shown) to the third plate 153. Instead an angled path 145 is provided through the plates 151 and 152. The angled path 145 can be set based on the amount of displacement between the first plate 151 and the second plate 152. For example, the angled path 145 may intersect the third plate 153 at a first angle 01. As such, the current generated in the third plate 153 can be attributed to ions that are only traveling at (or around) the selected angle of the angled path 145. That is, ions traveling at other angles are blocked by the first plate 151 and the second plate 152.

Referring now to FIG. 1B, a cross-sectional illustration of the sensor 150 at a second configuration is shown, in accordance with an embodiment. In an embodiment, the second configuration may be set by displacing the second plate 152 in a second direction relative to the first plate 151. For example, in FIG. 1A the second plate 152 is shifted right relative to the first plate 151, and in FIG. 1B the second plate 152 is shifted left relative to the first plate 151. Accordingly, the angled path 145 intersects the third plate 153 at a second angle θ₂ that is different than the first angle θ₁. Generally, the difference between the first angle θ₁ and the second angle θ₂ may be approximately 180° or less, approximately 160° or less, approximately 120° or less, or approximately 90° or less.

In order to provide a measure of different ion angles, the second plate 152 may be scanned between the first configuration in FIG. 1A and the second configuration in FIG. 1B. In some embodiments, the scan between the positions of FIG. 1A and FIG. 1B is a continuous scan. In other embodiments, the second plate 152 may be stopped at one or more positions between those shown in FIGS. 1A and 1B. Further, implementing a voltage sweep between the first plate 151 and the second plate 152 allows for both ion angle and ion energy density to be measured with a single sensor 150. Accordingly, the sensor 150 provides enhanced capabilities compared to existing RFEA solutions that are currently available.

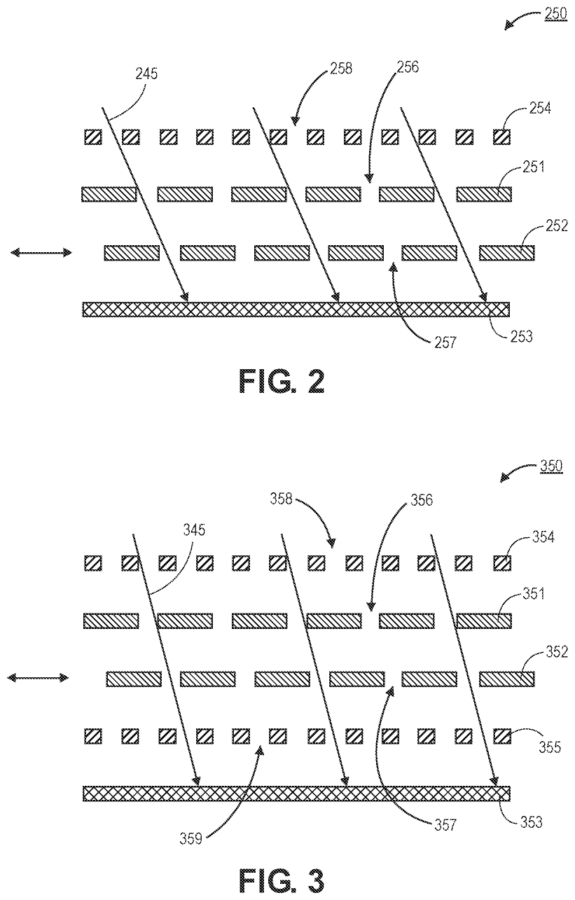

Referring now to FIG. 2, a cross-sectional illustration of an RFEA sensor 250 is shown, in accordance with an additional embodiment. In an embodiment, the sensor 250 may include a plurality of plates 251, 252, 253, and 254. The first plate 251 and the second plate 252 may be ion filter plates with openings 256 and 257, respectively. At least one of the first plate 251 and the second plate 252 may be laterally displaceable (as indicated by the double sided arrow) through the use of an actuator. As such, paths 245 with different angles can pass through the sensor 250 in order to reach the third plate 253. The first plate 251, the second plate 252, and the third plate 253 may be similar to the first plate 151, the second plate 152, and the third plate 153 described in greater detail above.

In an embodiment, a fourth plate 254 may be provided above the first plate 251. The fourth plate 254 may be considered an electron filter. The fourth plate 254 prevents electrons from the overlying plasma (not shown) from passing through the sensor and interacting with the third plate 253. As such, charge attributable to electrons is omitted from the sensor readings, and a true measure of the ion energy can be obtained.

In an embodiment, the fourth plate 254 may be an electrically conductive plate with openings 258. The fourth plate 254 may be any suitable electrically conductive material that is compatible with plasma environments. For example, the fourth plate 254 may comprise nickel, an alloy including nickel, stainless steel, aluminum, titanium, or the like.

The electrons from the plasma may be repelled by the fourth plate 254 by holding the fourth plate 254 at a certain voltage. Since the electrons have a negative charge, the fourth plate 254 may have a negative voltage in order to repel the electrons. In an embodiment, the fourth plate 254 is held at a substantially constant voltage. Though, in some instances, the voltage of the fourth plate 254 may be controlled to different set points. As used herein, a “substantially constant voltage” may refer to a voltage that fluctuates less than ten percent over a period of time.

Referring now to FIG. 3, a cross-sectional illustration of an RFEA sensor 350 is shown, in accordance with an additional embodiment. In an embodiment, the sensor 350 may include a plurality of plates 351, 352, 353, 354, and 355. The first plate 351 and the second plate 352 may be ion filter plates with openings 356 and 357, respectively. At least one of the first plate 351 and the second plate 352 may be laterally displaceable (as indicated by the double sided arrow) through the use of an actuator. As such, paths 345 with different angles can pass through the sensor 350 in order to reach the third plate 353. A fourth plate 354 may act as an electron filter. The first plate 351, the second plate 352, the third plate 353, and the fourth plate 354 may be similar to the first plate 251, the second plate 252, the third plate 253, and the fourth plate 254 described in greater detail above.

In an embodiment, the fifth plate 355 may be provided between the second plate 352 and the third plate 353. The fifth plate 355 may be a secondary electron filter. More particularly, as ions collide with the third plate 353, electrons may be ejected. The fifth plate 355 may be set to a voltage that attracts and consumes the ejected electrons. Accordingly, ejected electrons are prevented from recombining with the third plate 353 and artificially inflating the current attributable to ions.

In an embodiment, the fifth plate 355 may be an electrically conductive plate with openings 359. The fifth plate 355 may be any suitable electrically conductive material that is compatible with plasma environments. For example, the fifth plate 355 may comprise nickel, an alloy including nickel, stainless steel, aluminum, titanium, or the like.

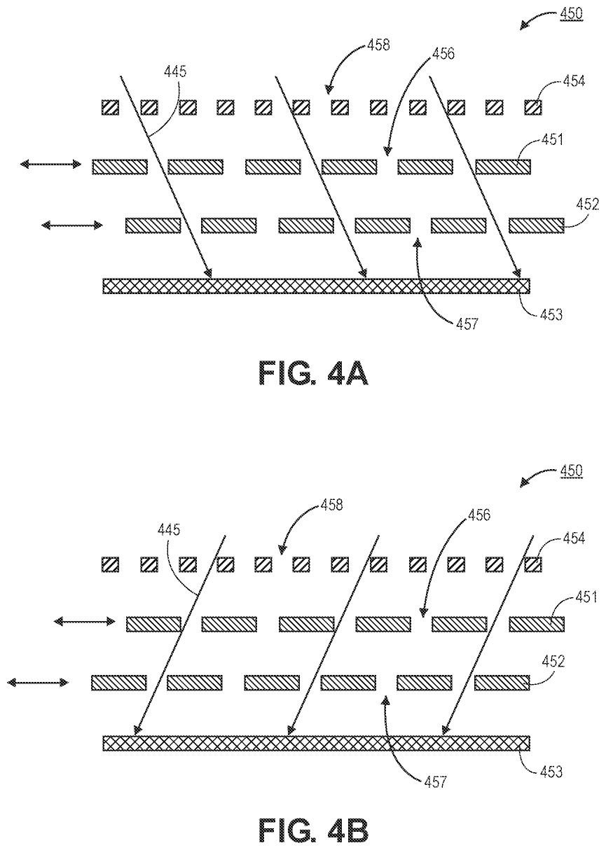

Referring now to FIG. 4A, a cross-sectional illustration of an RFEA sensor 450 is shown, in accordance with an embodiment. In an embodiment, the sensor 450 includes a first plate 451, a second plate 452, a third plate 453, and a fourth plate 454 arranged in a vertical stack. The first plate 451 and the second plate 452 may be ion filters with openings 456 and 457, respectively. The third plate 453 may be a collector, and the fourth plate 454 may be an electron filter with openings 458. The structure of the sensor 450 may be similar to the sensor 250 in FIG. 2.

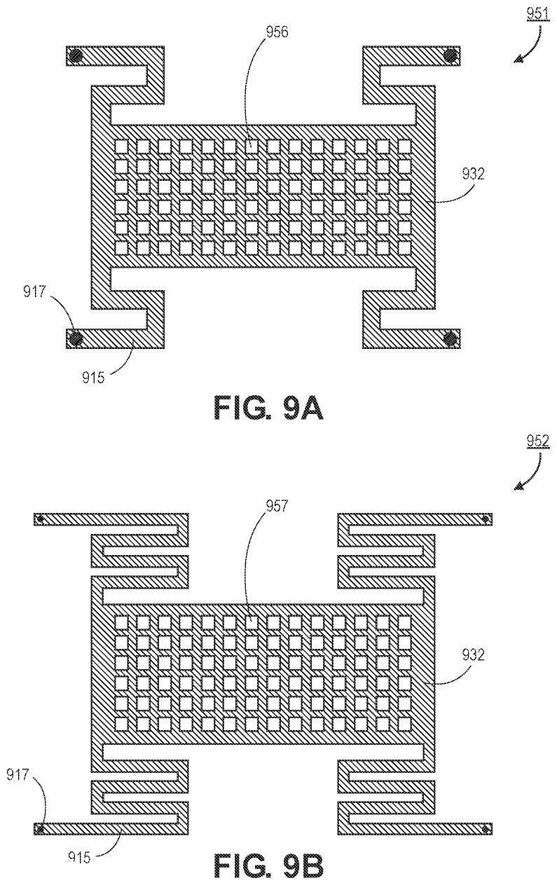

However, in FIG. 4A the sensor 450 may further comprise functionality to displace both the first plate 451 and the second plate 452, as indicated by the double sided arrow adjacent to each plate. In one embodiment, the first plate 451 is coupled to a first actuator and the second plate 452 is coupled to a second actuator. In such instances, the two actuators may operate independently in order to displace the plates 451 and 452 in order to provide paths 445 through the sensor at different angles. In a different embodiment, a single actuator may be used to displace both the first plate 451 and the second plate 452. Such a configuration may be possible by having plates 451 and 452 that have different designs. For example, a common force applied to both plates 451 and 452 may result in different amounts of displacement. An example of such a configuration is provided in greater detail below with respect to FIGS. 9A and 9B.

Referring now to FIG. 4B, a cross-sectional illustration of the sensor 450 is shown, in accordance with another embodiment. In an embodiment, the sensor 450 may be provided in a different configuration that provides a different angle for the path 445. For example, the path 445 in FIG. 4A may be at a first end of a range of angles, and the path 445 in FIG. 4B may be at a second end of the range of angles. By displacing the first plate 451 and the second plate 452 relative to each other with the one or more actuators, the sensor 450 can scan ion angles between the two extremes. Similar to other embodiments described above, the scanning of voltage differences between the first plate 451 and the second plate 452 can also be used to provide ion energy distributions. That is, embodiments disclosed herein enable the measurement of both ion energy distribution and ion angle.

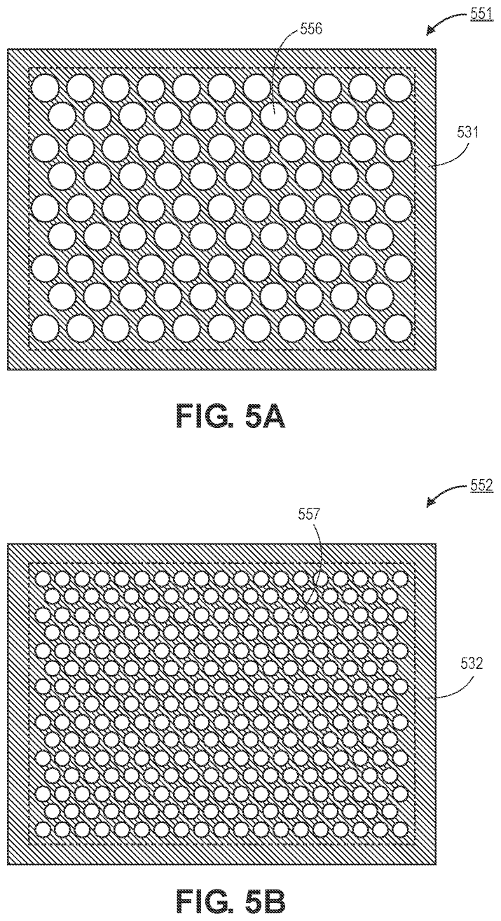

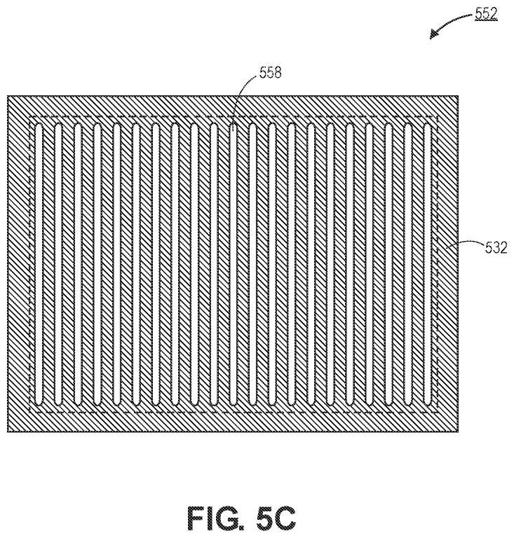

Referring now to FIGS. 5A and 5B, a pair of plan view illustrations of a first plate 551 (FIG. 5A) and a second plate 552 (FIG. 5B) are shown, in accordance with an embodiment. The embodiments shown in FIGS. 5A and 5B depict an example of a portion of the plates 551 and 552. Generally, the regions of the plates 551 and 552 that are depicted in FIGS. 5A and 5B are the regions that act as the ion filtering region. Additional portions of the plates 551 and 552 (such as connections to other layers, connections to actuators, supports, etc.) are omitted for simplicity.

Referring now to FIG. 5A, a plan view illustration of a portion of a first plate 551 is shown, in accordance with an embodiment. In an embodiment, the first plate 551 may comprise an outer frame 531. The frame 531 may be an electrically conductive layer that surrounds an aperture region. In an embodiment, the aperture region may comprise a plurality of openings 556. The openings 556 may be arranged in a grid across the plate 551. In some instances, the aperture region may be considered a screen. The openings 556 in FIG. 5 are circular. Though, openings 556 may have any suitable shape or shapes.

In the illustrated embodiment, all of the openings 556 have a similar dimension (e.g., diameter). Though, in other embodiments, the openings 556 may have non-uniform dimensions within the first plate 551. For example, openings 556 towards a middle of the first plate 551 may have a different dimension than openings towards a perimeter of the first plate 551. The openings 556 may have a diameter that is up to approximately 100 μm in some embodiments. For example, the openings 556 may have diameters that are between approximately 5 μm and approximately 25 μm in some instances.

Referring now to FIG. 5B, a plan view illustration of a second plate 552 is shown, in accordance with an embodiment. In an embodiment, the second plate 552 may also include a frame 532 that surrounds the openings 557. In an embodiment, the openings 557 may have a different dimension than the openings 556 in the first plate 551. For example, the openings 557 in the second plate 552 may be smaller than the openings 556 in the first plate 551. Similar to the openings 556, the openings 557 in the second plate 552 may have a diameter that is up to approximately 100 μm in some embodiments. For example, the openings 557 may have diameters that are between approximately 5 μm and approximately 25 μm in some instances. Further, the openings 557 may have non-uniform dimensions within the second plate 552. While both the openings 556 and the openings 557 are circular, embodiments are not limited to such configurations. For example, the openings 556 may be circular and the openings 557 may be rectangular, hexagonal, or any other polygonal shape.

Referring now to FIG. 5C, an example of a second plate 552 with non-circular openings 558 is shown, in accordance with a different embodiment. The second plate 552 may also include a frame 532 with openings 558 within the frame 532. The openings 558 may be elongated slots. The slot openings 558 may be oriented substantially orthogonally to the direction of travel of the second plate 552. As used herein, “substantially orthogonal” may refer to two planes or lines being oriented within 10° of having a 90° intersection. The use of such slot based openings 558 may improve reading accuracy in some instances. That is, as the second plate 552 is displaced, the length of the openings 558 remains constant. This allows for more consistent readings that do not need to be adjusted to account for changing geometries.

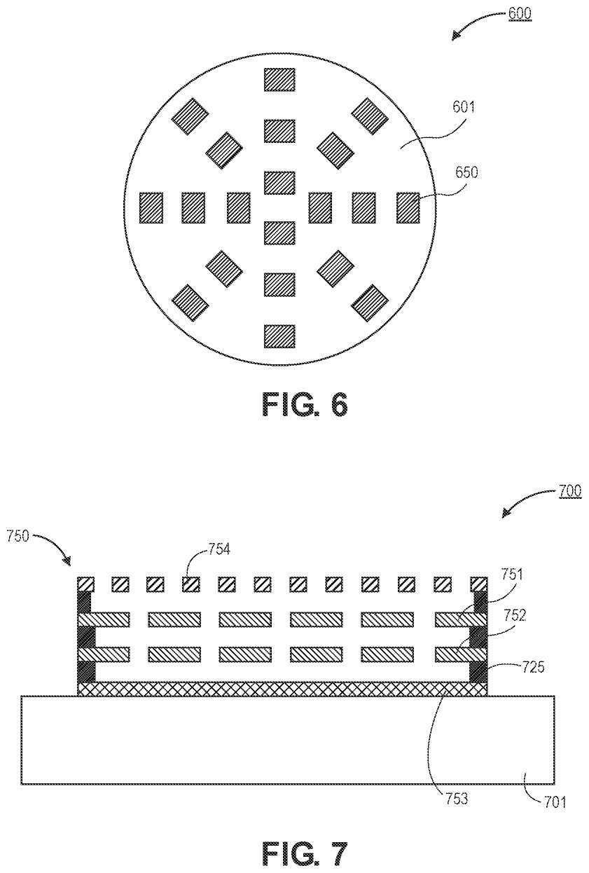

Referring now to FIG. 6, a plan view illustration of a system 600 is shown, in accordance with an embodiment. The system 600 may be a multi-sensor 650 apparatus that is used to provide spatial measurement of plasma ion angles and/or ion energy distributions. In an embodiment, the system 600 may comprise a substrate 601. The substrate 601 may have a standard wafer form factor (e.g., a 300 mm wafer, a 450 mm wafer, or the like). Though, other form factors and/or shapes may be used for the substrate 601. In an embodiment, the substrate 601 may include any suitable material that is compatible with plasma environments. For example, the substrate 601 may comprise one or more of silicon, other semiconductor material, glass, ceramic, metal, polymers, or the like.

In an embodiment, an array of sensors 650 may be provided across a surface of the substrate 601. In the illustrated embodiment, twenty sensors 650 are provided. Though, it is to be appreciated that any number of sensors 650 (e.g., one or more) may be provided on the substrate 601. Increasing the number of sensors 650 can lead to finer detail in the spatial mapping of plasma properties. Further, there is no limit to the particular pattern or arrangement of the sensors 650. The sensors 650 may be similar to any of the RFEA sensors described in greater detail herein. For example, the sensors 650 may include one or more laterally displaceable ion filter plates. In an embodiment, the sensors 650 may enable measurements of plasma properties that include ion angles and/or ion energy distributions.

Referring now to FIG. 7, a cross-sectional illustration of a portion of a system 700 is shown, in accordance with an embodiment. As shown, the sensor 750 is provided over a top surface of the substrate 701. The sensor 750 may include a first plate 751, a second plate 752, a third plate 753, and a fourth plate 754. In an embodiment, the plates 751-754 may be arranged in a vertical stack and separated from each other by insulating spacers 725. The first plate 751 and the second plate 752 may be ion filters. One or both of the first plate 751 and the second plate 752 may be displaceable relative to each other through connection to one or more actuators (not shown). The third plate 753 may be a collector that is coupled to a charge collection circuit (not shown). The fourth plate 754 may be an electron filter. The sensor 750 may be similar to any of the RFEA sensor architectures described in greater detail herein.

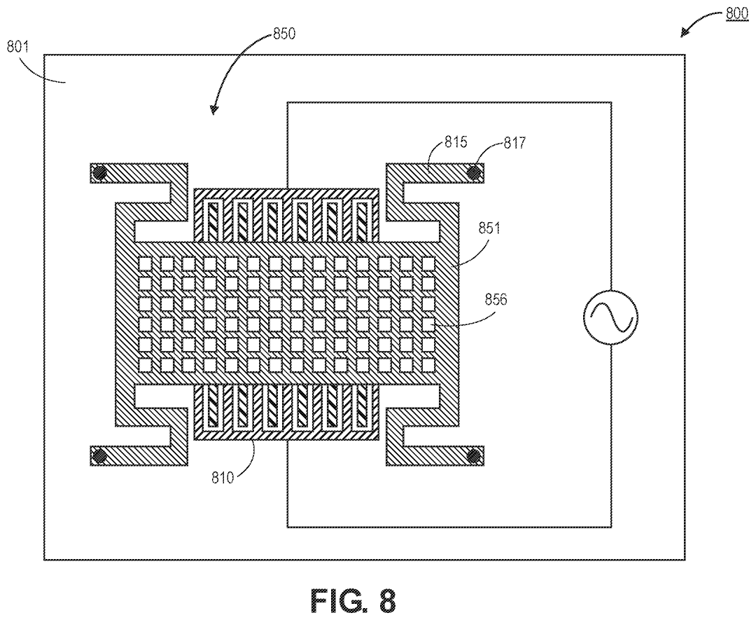

Referring now to FIG. 8, a plan view illustration of a portion of a system 800 is shown, in accordance with an embodiment. In the illustrated embodiment, an actuator 810 is provided between the substrate 801 and a plate 851. The plate 851 may include openings 856. In an embodiment, the plate 851 may be one of the ion filtering plates in an RFEA sensor 850, such as any of the RFEA sensors described herein. The additional plates of the sensor 850 are omitted for clarity.

In an embodiment, the actuator 810 may include any type of actuator, such as an electrostatic actuator, a piezoelectric actuator, a thermally driven actuator, or a memory-alloy actuator. For example, the actuator 810 in FIG. 8 is an electrostatic comb drive that is coupled to an alternating voltage source. In an embodiment, the electrostatic force of the actuator 810 can result in the displacement of the plate 851 (e.g., up/down and/or left/right in FIG. 8). Spring arms 815 can couple the plate 851 to anchors 817 that are attached to the substrate 801. Application of the electrostatic force by the actuator 810 causes the spring arms 815 to deflect in order to provide a controlled displacement of the plate 851.

Referring now to FIGS. 9A and 9B, a pair of plan view illustrations depict various architectures for different plates 951 and 952. In an embodiment, the plate 951 in FIG. 9A and the plate 952 in FIG. 9B may be used in conjunction with each other in a single RFEA sensor. The differences in design (particularly with respect to the spring arms 915) allows for the plates 951 and 952 to be displaced in different amounts through the use of a single actuator.

Referring now to FIG. 9A, a plan view illustration of a first plate 951 is shown, in accordance with an embodiment. The first plate 951 may include a frame 932 that surrounds an array of openings 956. In an embodiment, corners of the frame 932 may be coupled to anchors 917 through spring arms 915. The spring arms 915 may have a first spring constant.

Referring now to FIG. 9B, a plan view illustration of a second plate 952 is shown, in accordance with an embodiment. The second plate 952 may include a frame 932 that surrounds an array of openings 957. In an embodiment, corners of the frame 932 may be coupled to anchors 917 through spring arms 915. The spring arms 915 may have a second spring constant that is different than the first spring constant.

In some embodiments, the second spring constant may be an integer multiple of the first spring constant. Though, the first and second spring constant may have differences of any magnitude. In the case of the second spring constant being twice the first spring constant and for a given applied force by the actuator, the first plate 951 may displace approximately twice as far as the second plate 952. In this manner, both plates 951 and 952 can be displaced to enable different ion angles to pass through the filter while only needing a single actuator.

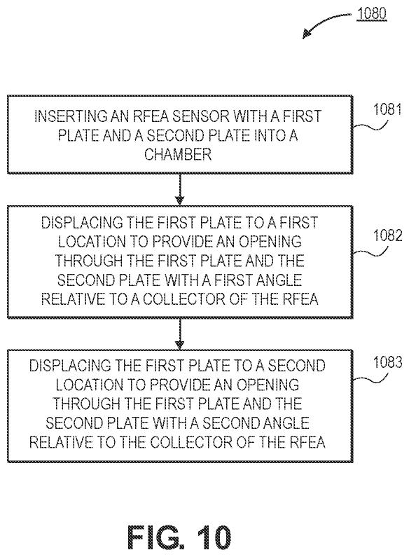

Referring now to FIG. 10, a process flow diagram of a process 1080 for measuring various ion angles in a plasma is shown, in accordance with an embodiment. In an embodiment, the process 1080 may begin with operation 1081, which comprises inserting an RFEA sensor with a first plate and a second plate into a chamber. In an embodiment, the RFEA sensor may be similar to any of the RFEA sensors described in greater detail herein. For example, the first plate and the second plate may be provided over a collector. An electron filter may also be provided above the plates and/or between the collector and the plates. In an embodiment, one or both of the plates may be coupled to an actuator in order to displace the plates relative to each other.

In an embodiment, the process 1080 continues with operation 1082, which comprises displacing the first plate to a first location to provide an opening through the first plate and the second plate. In an embodiment, the opening defines a path that has a first angle relative to the collector of the RFEA sensor. While in the first location, the RFEA sensor is configured to collect ions that travel from the plasma at the first angle.

In an embodiment, the process 1080 continues with operation 1083, which comprises displacing the first plate to a second location to provide an opening through the first plate and the second plate. In an embodiment, the opening defines a path that has a second angle relative to the collector of the RFEA sensor. While in the second location, the RFEA sensor is configured to collect ions that travel from the plasma at the second angle.

In some embodiments, the first location and the second location of the first plate may be at opposite ends of a scanning range. That is, additional positions between the first location and the second location can be used in order to detect many different ion angles. The first plate can be scanned continuously between the first location and the second location. In other embodiments, the first plate can stop at a plurality of locations between the first location and the second location. In the embodiment described in process 1080, the first plate is displaced in isolation. In other embodiments, both the first plate and the second plate can be displaced in order to enable readings of various ion angles.

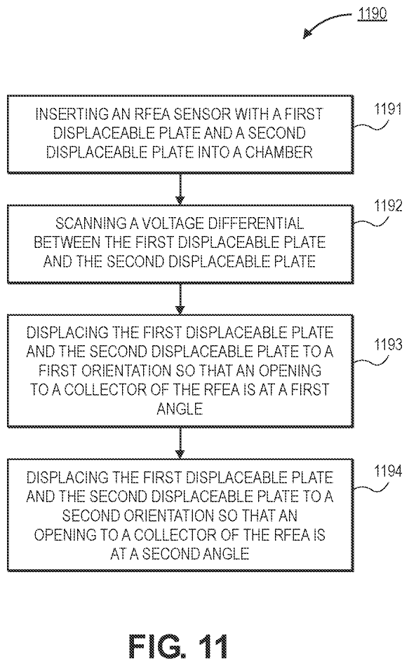

Referring now to FIG. 11, a process flow diagram describing a process 1190 for measuring ion energy distributions and ion angle is provided in accordance with an embodiment. In an embodiment, the process 1190 may begin with operation 1191, which comprises inserting an RFEA sensor with a first displaceable plate and a second displaceable plate into a chamber. In an embodiment, the RFEA sensor may be similar to any of the RFEA sensors described in greater detail herein.

In an embodiment, the process 1190 may continue with operation 1192, which comprises scanning a voltage differential between the first displaceable plate and the second displaceable plate. This process allows for ions with various energies to pass through the filter in order to reach the underlying collector. As such, an ion energy distribution can be obtained.

In an embodiment, the process 1190 may continue with operation 193, which comprises displacing the first displaceable plate and the second displaceable plate to a first orientation so that an opening to a collector of the RFEA sensor defines a path with a first angle. The path allows for ions with the first angle to pass through to the collector. In an embodiment, operation 1192 may be repeated while the sensor is in the first orientation in order to determine an ion energy distribution for that particular angle.

In an embodiment, process 1190 may continue with operation 1194, which comprises displacing the first displaceable plate and the second displaceable plate to a second orientation so that an opening to a collector of the RFEA sensor defines a path with a second angle. The path allows for ions with the second angle to pass through to the collector. In an embodiment, operation 1192 may be repeated while the sensor is in the second orientation in order to determine an ion energy distribution for that particular angle.

In some embodiments, the first orientation and the second orientation of the first plate and the second plate may be at opposite ends of a scanning range. That is, additional orientations between the first orientation and the second orientation can be used in order to detect many different ion angles. The first and second plates can be scanned continuously between the first orientation and the second orientation. In other embodiments, the first and second plates can stop at a plurality of different orientations between the first orientation and the second orientation. In the embodiment described in process 1190, displacement of both the first plate and the second plate is described. In other embodiments, either the first plate or the second plate can be displaced in isolation in order to enable readings of various ion angles.

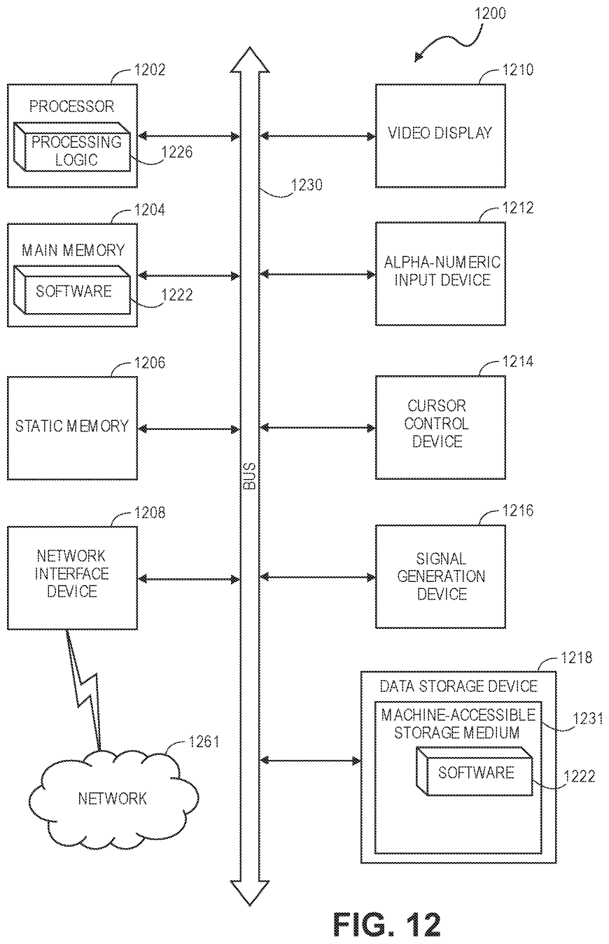

Referring now to FIG. 12, a block diagram of an exemplary computer system 1200 of a processing tool is illustrated in accordance with an embodiment. In an embodiment, computer system 1200 is coupled to and controls processing in the processing tool. Computer system 1200 may be connected (e.g., networked) to other machines in a Local Area Network (LAN), an intranet, an extranet, or the Internet. Computer system 1200 may operate in the capacity of a server or a client machine in a client-server network environment, or as a peer machine in a peer-to-peer (or distributed) network environment. Computer system 1200 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 1200, the term “machine” shall also be taken to include any collection of machines (e.g., computers) that individually or jointly execute a set (or multiple sets) of instructions to perform any one or more of the methodologies described herein.

Computer system 1200 may include a computer program product, or software 1222, having a non-transitory machine-readable medium having stored thereon instructions, which may be used to program computer system 1200 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 1200 includes a system processor 1202, a main memory 1204 (e.g., read-only memory (ROM), flash memory, dynamic random access memory (DRAM) such as synchronous DRAM (SDRAM) or Rambus DRAM (RDRAM), etc.), a static memory 1206 (e.g., flash memory, static random access memory (SRAM), etc.), and a secondary memory 1218 (e.g., a data storage device), which communicate with each other via a bus 1230.

System processor 1202 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 1202 may also be one or more special-purpose processing devices such as an application specific integrated circuit (ASIC), a field programmable gate array (FPGA), a digital signal system processor (DSP), network system processor, or the like. System processor 1202 is configured to execute the processing logic 1226 for performing the operations described herein.

The computer system 1200 may further include a system network interface device 1208 for communicating with other devices or machines. The computer system 1200 may also include a video display unit 1210 (e.g., a liquid crystal display (LCD), a light emitting diode display (LED), or a cathode ray tube (CRT)), an alphanumeric input device 1212 (e.g., a keyboard), a cursor control device 1214 (e.g., a mouse), and a signal generation device 1216 (e.g., a speaker).

The secondary memory 1218 may include a machine-accessible storage medium 1232 (or more specifically a computer-readable storage medium) on which is stored one or more sets of instructions (e.g., software 1222) embodying any one or more of the methodologies or functions described herein. The software 1222 may also reside, completely or at least partially, within the main memory 1204 and/or within the system processor 1202 during execution thereof by the computer system 1200, the main memory 1204 and the system processor 1202 also constituting machine-readable storage media. The software 1222 may further be transmitted or received over a network 1220 via the system network interface device 1208. In an embodiment, the network interface device 1208 may operate using RF coupling, optical coupling, acoustic coupling, or inductive coupling.

While the machine-accessible storage medium 1232 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a first plate with an array of first openings, wherein the first plate is electrically conductive;
a second plate with an array of second openings below the first plate, wherein the second plate is electrically conductive;
an actuator coupled to the first plate or the second plate, wherein the actuator is configured to displace one of the first plate or the second plate; and
a third plate below the second plate, wherein the third plate is electrically conductive.

2. The apparatus of claim 1, wherein the third plate is coupled to a charge collection circuit.

3. The apparatus of claim 1, wherein the first plate can be actuated between a first position and a second position, wherein the first position allows for a first line to pass through the first plate and the second plate and intersect the third plate at a first angle, and wherein the second position allows for a second line to pass through the first plate and the second plate and intersect the third plate at a second angle.

4. The apparatus of claim 1, wherein the first plate, the second plate, and the third plate are configured to be held at different voltages.

5. The apparatus of claim 1, further comprising:
a second actuator, wherein the second actuator is coupled to the first plate or the second plate that is not coupled to the actuator, and wherein the actuator and the second actuator can displace the first plate and the second plate in different directions.

6. The apparatus of claim 1, further comprising:
a fourth plate with third openings over the first plate, wherein the fourth plate is configured to be held at a different voltage than the first plate.

7. The apparatus of claim 1, further comprising:
a fourth plate between the second plate and the third plate, wherein the fourth plate is configured to be held at a voltage different than the second plate and the third plate.

8. The apparatus of claim 1, wherein the actuator is an electrostatic actuator, a piezoelectric actuator, a thermally driven actuator, or a memory-alloy actuator.

9. The apparatus of claim 7, wherein the actuator is a comb drive.

10. The apparatus of claim 1, wherein the second plate comprises spring arms.

11. An apparatus, comprising:
a substrate; and
a sensor on the substrate, wherein the sensor comprises:
a collector plate;
a first plate with first openings over the collector, wherein the first plate is configured to be displaced in a plane substantially parallel to a top surface of the collector plate; and
a second plate with second openings over the first plate.

12. The apparatus of claim 11, wherein the first plate is displaced by an actuator.

13. The apparatus of claim 11, wherein the second plate is configured to be displaced in a plane substantially parallel to the top surface of the collector plate.

14. The apparatus of claim 11, further comprising a third plate with third openings over the second plate.

15. The apparatus of claim 11, further comprising a third plate with third openings between the collector and the first plate.

16. The apparatus of claim 11, further comprising:
a plurality of second sensors on the substrate, wherein the second sensors are similar in structure to the sensor.

17. An apparatus, comprising:
a substrate;
a plurality of sensors distributed across a surface of the substrate, wherein each sensor comprises:
a collector, wherein the collector is configured to measure a current induced by ions that collide with the collector; and
an ion filter over the collector, wherein the ion filter comprises:
a first plate with first openings; and
a second plate with second openings over the first plate, wherein one or both of the first plate and the second plate are displaceable in a plane substantially parallel to a top surface of the collector plate.

18. The apparatus of claim 17, wherein displacement of one or both of the first plate and the second plate enables detection of ions traveling at different angles relative to the collector.

19. The apparatus of claim 17, further comprising:
an electron filter over the ion filter.

20. The apparatus of claim 17, wherein displacement of one or both of the first plate and the second plate is driven by an actuator that is an electrostatic actuator, a piezoelectric actuator, a thermally driven actuator, or a memory-alloy actuator.
